(19) United States
(12) Patent Application Publication
(10) Pub. No.: US 2025/0125147 A1
(43) Pub. Date: Apr. 17, 2025

(54) METHOD OF FORMING LINE PATTERN IN SEMICONDUCTOR DEVICE

(71) Applicant: NANYA TECHNOLOGY CORPORATION, New Taipei city (TW)

(72) Inventors: Chao Yuan CHENG, Taipei City (TW); Chan Hen YANG, Taipei City (TW)

(21) Appl. No.: 18/487,617

(22) Filed: Oct. 16, 2023

(51) Int. Cl. H01L 21/027; H01L 21/033; H01L 21/311; H01L 21/762

(52) U.S. Cl. CPC H01L 21/0274; H01L 21/0337; H01L 21/31144; H01L 21/76229

(57) ABSTRACT

A method of forming a line pattern in a semiconductor device includes forming a first photoresist layer having a first trench over a substrate, filling a first material in the first trench, forming a second photoresist layer having a second trench over the first photoresist layer, filling a second material in the second trench, and after filling the second material in the second trench, removing the first photoresist layer and the second photoresist layer.

### BACKGROUND

### Field of Disclosure

The present disclosure relates to a method of forming a line pattern in a semiconductor device.

### Description of Related Art

Photolithography processes is one of the basic step during forming the semiconductor devices. In the photolithography process, a photoresist layer having a certain pattern is formed on a layer. Subsequently, the pattern of the photoresist layer is filled with certain material, and then the photoresist layer is removed to form a patterned layer on the layer below. The photoresist layer may be affected by standing wave effect, which leads to line edge roughness (LER) or line width roughness (LWR) issue of the patterned layer to be formed. The standing wave effect is caused by the formation of the standing wave, which results from the interference between incident light to the photoresist layer and light reflected by the layer below the photoresist layer, in the photoresist layer. The standing wave formed in the photoresist layer leads to periodic underexposed portions and overexposed portions of the photoresist layer, and cause jagged sidewalls of the photoresist layer. Therefore, the standing wave effect causes the roughness issue of the photoresist layer.

Generally, the standing wave effect may be reduced by providing a hard mask layer below the photoresist layer. The n/k ratio (ratio of refractive index to extinction coefficient) of the hard mask layer is adjusted to reduce the light reflected by the layer below the photoresist layer, and thus reduce the standing wave effect in the photoresist layer. Another method of reducing the standing wave effect is post exposure bake (PEB). The heat provided by PEB rearranges the photoacid molecules in the underexposed portions and overexposed portions of the photoresist layer to reduce the jagged sidewalls of the photoresist layer. The heat also drives the deprotection reactions in the photoresist layer and promotes the diffusion of the photoacid molecules in the photoresist layer. However, not all the layers are suitable for the hard mask layer to be formed thereon, and PEB is not able to reduce the standing wave effect to a significant degree.

### SUMMARY

Some embodiments of the present disclosure provide a method of forming a line pattern in a semiconductor device, including forming a first photoresist layer having a first trench over a substrate, filling a first material in the first trench, forming a second photoresist layer having a second trench over the first photoresist layer, filling a second material in the second trench, and after filling the second material in the second trench, removing the first photoresist layer and the second photoresist layer.

In some embodiments, the second trench is aligned with the first trench.

In some embodiments, the second material is the same as the first material.

In some embodiments, the second material is different from the first material.

In some embodiments, after filling the first material in the first trench, a top surface of the first material is level with a top surface of the first photoresist layer.

In some embodiments, filling the first material in the first trench includes forming the first material overfilling the first trench, and removing an excess portion of the first material by performing a planarization process until the top surface of the first photoresist layer is exposed.

In some embodiments, after filling the second material in the second trench, a top surface of the first material is level with a top surface of the second photoresist layer.

In some embodiments, filling the second material in the second trench includes forming the second material overfilling the second trench, and removing an excess portion of the second material by performing a planarization process until the top surface of the second photoresist layer is exposed.

In some embodiments, the first photoresist layer and the second photoresist layer are removed through a single removal process.

In some embodiments, forming the first photoresist layer having the first trench includes patterning the first photoresist layer, and forming the second photoresist layer having the second trench comprises patterning the second photoresist layer, and wherein patterning the first photoresist layer and patterning the second photoresist layer are performed using a same mask.

Some embodiments of the present disclosure provide a method of forming a line pattern in a semiconductor device, including forming a first photoresist layer having a first trench over a substrate, in which the first photoresist layer has a first thickness, filling a first material in the first trench, forming a second photoresist layer having a second trench over the first photoresist layer, the second photoresist layer being in contact with the first photoresist layer, in which the second photoresist layer has a second thickness, filling a second material in the second trench, and removing the first photoresist layer and the second photoresist layer.

In some embodiments, opposite sidewalls of the second material is aligned with opposite sidewalls of the first material.

In some embodiments, the first photoresist layer and the second photoresist layer are made of a same material, and the first thickness is substantially the same as the second thickness.

In some embodiments, after filling the first material in the first trench, the first material and the first photoresist layer have substantially a same height.

In some embodiments, filling the first material in the first trench includes forming the first material overfilling the first trench, and removing an excess portion of the first material by performing a planarization process until a top surface of the first photoresist layer is exposed.

In some embodiments, after filling the second material in the second trench, the second material and the second photoresist layer have substantially a same height.

In some embodiments, filling the second material in the second trench includes forming the second material overfilling the second trench, and removing an excess portion of the second material by performing a planarization process until a top surface of the second photoresist layer is exposed.

In some embodiments, the first material is filled in the first trench of the first photoresist layer by a first selective epitaxial growth process, and the second material is filled in the second trench of the second photoresist layer by a second selective epitaxial growth process.

In some embodiments, the first material and the second material are made of a semiconductor material.

In some embodiments, the substrate is made of a semiconductor material.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-7 illustrate cross-section views of forming a line pattern in a semiconductor device in some embodiments of the present disclosure.

FIGS. 8-10 illustrate cross-section views of forming a line pattern in a semiconductor device in some other embodiments of the present disclosure.

FIGS. 11-14 illustrate cross-section views of forming a line pattern in a semiconductor device in some other embodiments of the present disclosure.

FIGS. 15-19 illustrate cross-section views of forming a line pattern in a semiconductor device in some other embodiments of the present disclosure.

### DETAILED DESCRIPTION

Some embodiments of the present disclosure are used to form a line pattern with less roughness issue. The line pattern may be used as conductive lines. Moreover, the intersecting line pattern may be used to define holes. The line pattern may be formed by filling the certain material in the trenches in the photoresist layer. The photoresist layer with different thickness may cause the standing wave effect in varying degrees. For example, the thicker photoresist layer causes greater degree of the standing wave effect, and the thinner photoresist layer cause less degree of the standing wave effect. The greater degree of the standing wave effect may cause greater roughness, such as footing or undercut, of the photoresist layer. Therefore, the line pattern is formed by repeating filling the certain material in the trenches in the photoresist layers, in which one photoresist layer is over another photoresist layer, instead of filling the certain material in the trenches in a single photoresist layer. The photoresist layers are thin enough, so the photoresist layers are not affected by the standing wave effect much. As a result, the line pattern with less roughness issue is formed.

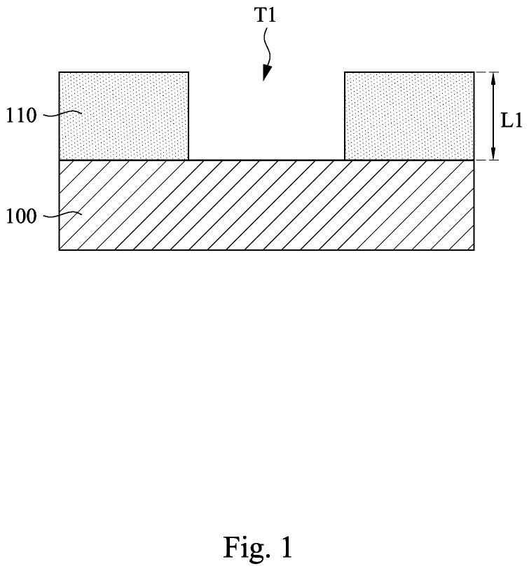

FIGS. 1-7 illustrate cross-section views of forming a line pattern in a semiconductor device in some embodiments of the present disclosure. Referring to FIG. 1, a first photoresist layer 110 having a first trench T1 is formed over a substrate 100. Specifically, the first photoresist layer 110 having the first trench T1 is formed over the substrate 100 by performing a first patterning process, in which the first photoresist layer 110 has a first thickness L1. The first thickness L1 is chosen so that the first photoresist layer 110 is thin enough, and the standing wave effect does not affect the first photoresist layer 110 or lead to the roughness of the first photoresist layer 110. In some embodiments, the first thickness L1 is in a range from 30 nm to 50 nm. After forming the first photoresist layer 110, the first trench T1 exposes the substrate 100. In some embodiments, the substrate 100 may be any layer in the semiconductor device where the line pattern is to be formed over, such as hard mask, underlayer, bottom anti-reflective coating (BARC), dielectric anti reflective coating (DARC).

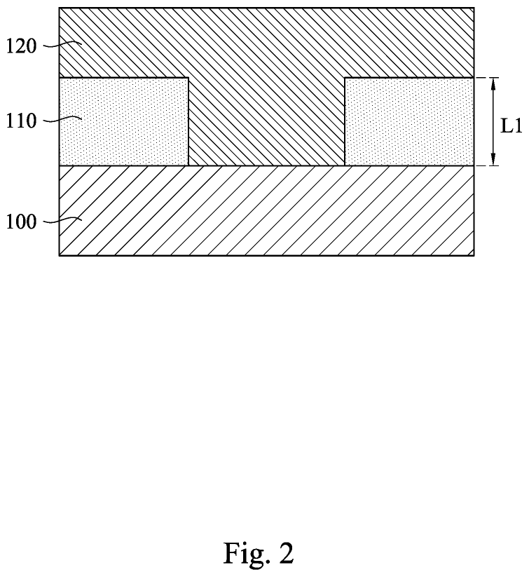

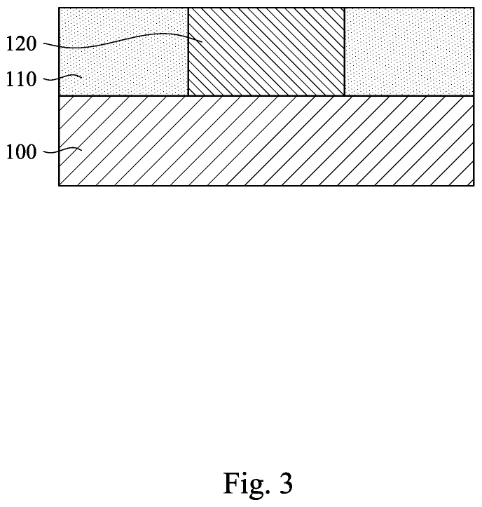

Referring to FIG. 2, a first material 120 is formed overfilling the first trench T1, and then referring to FIG. 3, an excess portion of the first material 120 is removed by performing a planarization process until the top surface of the first photoresist layer 110 is exposed. As a result, the first material 120 is filled in the first trench T1. After filling the first material 120 in the first trench T1, a top surface of the first material 120 is level with a top surface of the first photoresist layer 110, and the first material 120 and the first photoresist layer 110 have substantially a same height. The first material 120 may be silicon, oxide, or other suitable material.

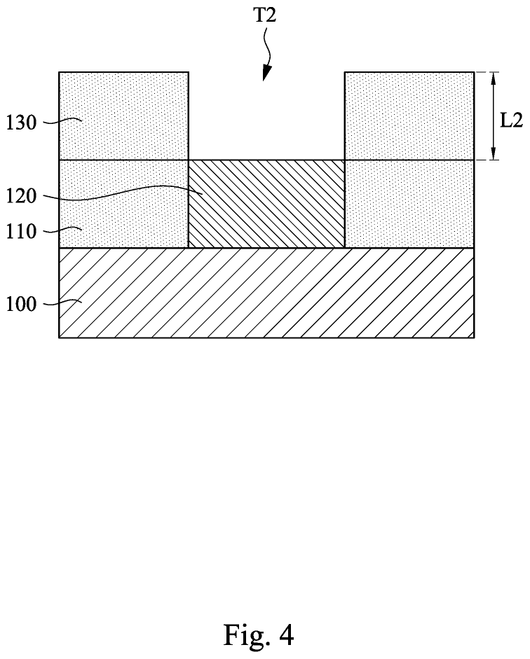

Referring to FIG. 4, a second photoresist layer 130 having a second trench T2 is formed over the first photoresist layer 110, and the second photoresist layer 130 is in contact with the first photoresist layer 110. Specifically, the second photoresist layer 130 having the second trench T2 is formed over the first photoresist layer 110 by performing a second patterning process, in which the second photoresist layer 130 has a second thickness L2. The second thickness L2 is chosen so that the second photoresist layer 130 is thin enough, and the standing wave effect does not affect the second photoresist layer 130 or lead to the roughness of the second photoresist layer 130. In some embodiments, the first photoresist layer 110 and the second photoresist layer 130 are made of the same material, and the first thickness L1 (see FIG. 1) is substantially the same as the second thickness L2, but the present disclosure is not limited thereto. In some embodiments, the first photoresist layer 110 and the second photoresist layer 130 may be patterned with a same mask, such that the position and the shape of the second trench T2 is the same as the first trench T1 of the first photoresist layer 110 (see FIG. 1). The second trench T2 is substantially aligned with the first trench T1 after forming the second photoresist layer 130. Stated another way, opposite sidewalls of second trench T2 may be substantially aligned with opposite sidewalls of the first material 120.

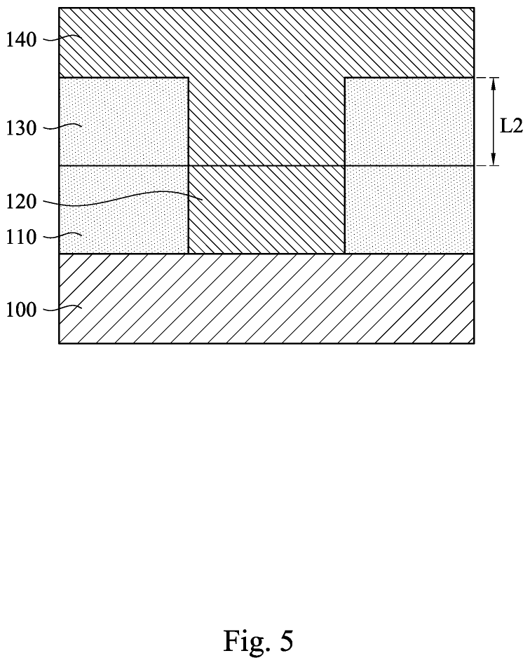

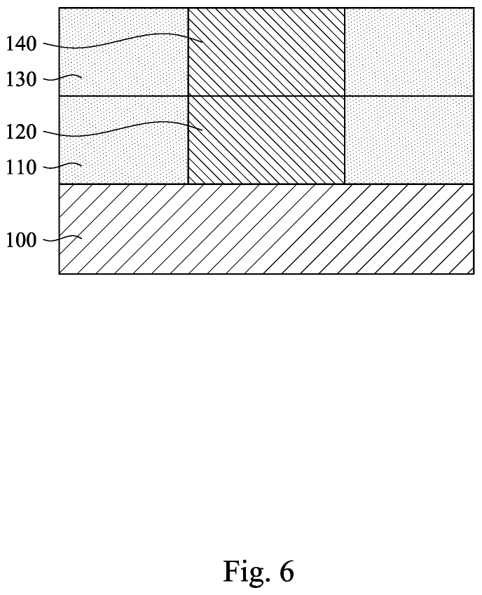

Referring to FIG. 5, a second material 140 is formed overfilling the second trench T2, and then referring to FIG. 6, an excess portion of the second material 140 is removed by performing a planarization process until the top surface of the second photoresist layer 130 is exposed. As a result, the second material 140 is filled in the second trench T2. After filling the second material 140 in the second trench T2, a top surface of the second material 140 is level with a top surface of the second photoresist layer 130, and the second material 140 and the second photoresist layer 130 have substantially a same height. The opposite sidewalls of the second material 140 may be substantially aligned with the opposite sidewalls of the first material 120. In some embodiments, the second material 140 may be the same as the first material 120.

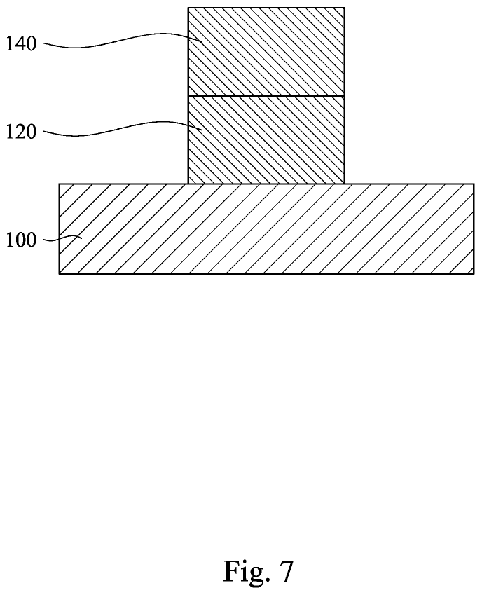

Referring to FIG. 7, after filling the second material 140 in the second trench T2, the first photoresist layer 110 and the second photoresist layer 130 are removed. In some embodiments, the first photoresist layer 110 and the second photoresist layer 130 are removed by an etching process. In some other embodiments, the first photoresist layer 110 and the second photoresist layer 130 are removed using ashing process or stripping. In some embodiments where the first photoresist layer 110 and the second photoresist layer 130 are made of the same material, the first photoresist layer 110 and the second photoresist layer 130 can be removed together in a single removal process as discussed above. As a result, the first material 120 and the second material 140 remain over the substrate 100 and form a line pattern. Since the first photoresist layer 110 and the second photoresist layer 130 are thin enough and do not cause severe standing wave effect, the roughness of the first photoresist layer 110 and the second photoresist layer 130 is reduced. The line pattern (i.e. the first material 120 and the second material 140) formed in the first photoresist layer 110 and the second photoresist layer 130 has less roughness issue. Therefore, in the case that the thickness of the line pattern in the following two situations is the same, the line pattern formed in the present disclosure has a better profile compared to the line pattern formed in a single photoresist layer.

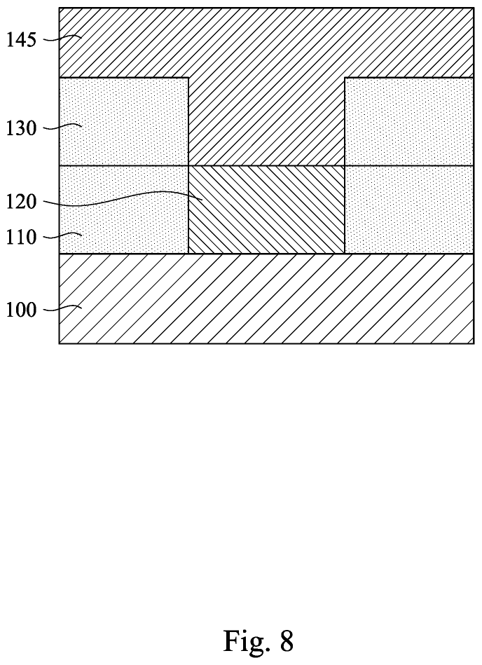

FIGS. 8-10 illustrate cross-section views of forming a line pattern in a semiconductor device in some other embodiments of the present disclosure. The forming method of the line pattern in FIGS. 8-10 is similar to the forming method of the line pattern in FIGS. 1-7. Specifically, after the process in FIG. 4 is complete, the processes in FIGS. 8-10 instead of the processes in FIGS. 5-7 are performed.

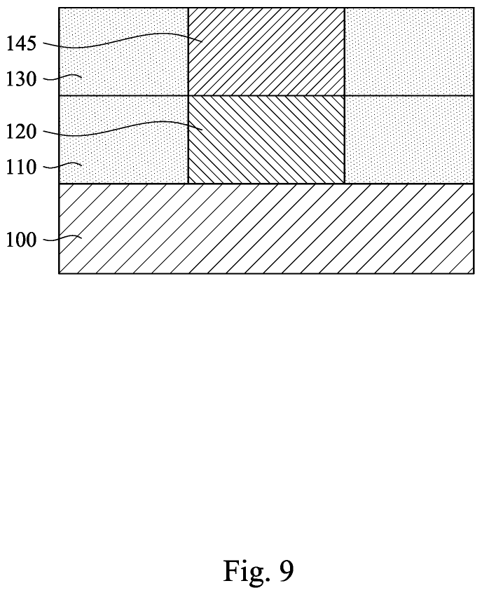

Referring to FIG. 8, after the process in FIG. 4, a second material 145 is formed overfilling the second trench T2, and then referring to FIG. 9, an excess portion of the second material 145 is removed by performing a planarization process until the top surface of the second photoresist layer 130 is exposed. As a result, the second material 145 is filled in the second trench T2. After filling the second material 145 in the second trench T2, a top surface of the second material 145 is level with a top surface of the second photoresist layer 130. In some embodiments, the second material 145 may be different from the first material 120.

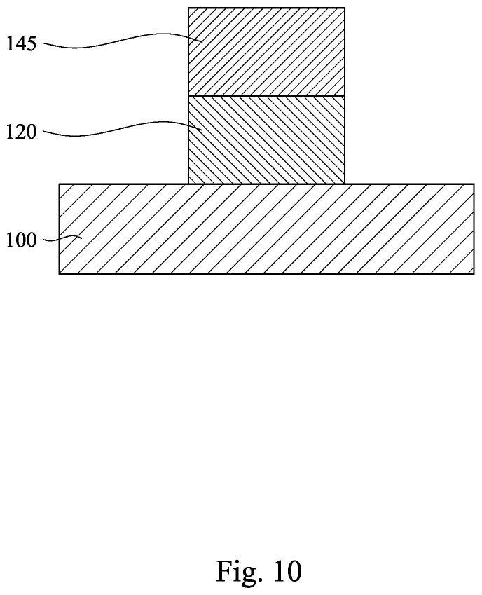

Referring to FIG. 10, after filling the second material 145 in the second trench T2, the first photoresist layer 110 and the second photoresist layer 130 are removed. In some embodiments, the first photoresist layer 110 and the second photoresist layer 130 are removed by an etching process. As a result, the first material 120 and the second material 145 remain over the substrate 100 and form a line pattern. Since the first photoresist layer 110 and the second photoresist layer 130 are thin enough and do not cause severe standing wave effect, the roughness of the first photoresist layer 110 and the second photoresist layer 130 is reduced. The line pattern (i.e. the first material 120 and the second material 145) formed in the first photoresist layer 110 and the second photoresist layer 130 has less roughness issue. Therefore, in the case that the thickness of the line pattern in the following two situations is the same, the line pattern formed in the present disclosure has a better profile compared to the line pattern formed in a single photoresist layer.

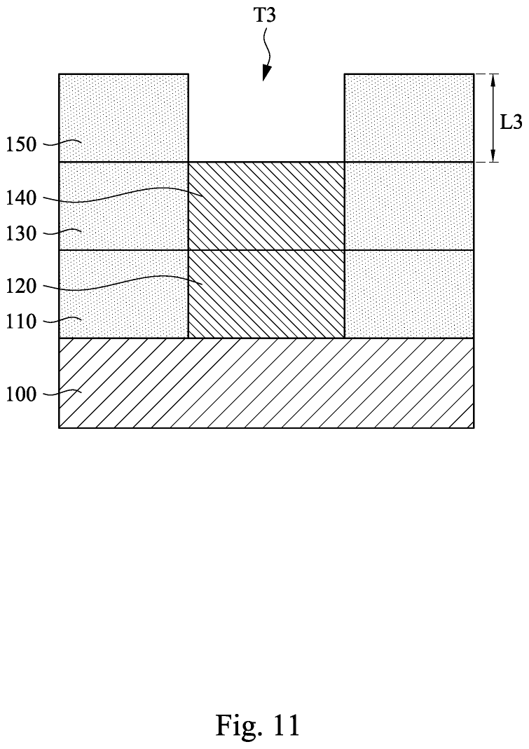

FIGS. 11-14 illustrate cross-section views of forming a line pattern in a semiconductor device in some other embodiments of the present disclosure. The forming method of the line pattern in FIGS. 11-14 is similar to the forming method of the line pattern in FIGS. 1-7. Specifically, after the process in FIG. 7 is complete, the processes in FIGS. 1-14 are continued.

Referring to FIG. 11, a third photoresist layer 150 having a third trench T3 is formed over the second photoresist layer 130, and the third photoresist layer 150 is in contact with the second photoresist layer 130. Specifically, the third photoresist layer 150 having the third trench T3 is formed over the second photoresist layer 130 by performing a third patterning process, in which the third photoresist layer 150 has a third thickness L3. The third thickness L3 is chosen so that the second photoresist layer 130 is thin enough, and the standing wave effect does not affect the third photoresist layer 150 or lead to the roughness of the third photoresist layer 150. In some embodiments, the first photoresist layer 110, the second photoresist layer 130 and the third photoresist layer 150 are made of the same material, and the third thickness L3 is the substantially same as the first thickness L1 (see FIG. 1) and the second thickness L2 (see FIG. 4), but the present disclosure is not limited thereto. The third trench T3 is substantially aligned with the second trench T2 after forming the third photoresist layer 150. Stated another way, opposite sidewalls of the third trench T3 may be substantially aligned with the opposite sidewalls of the second material 140.

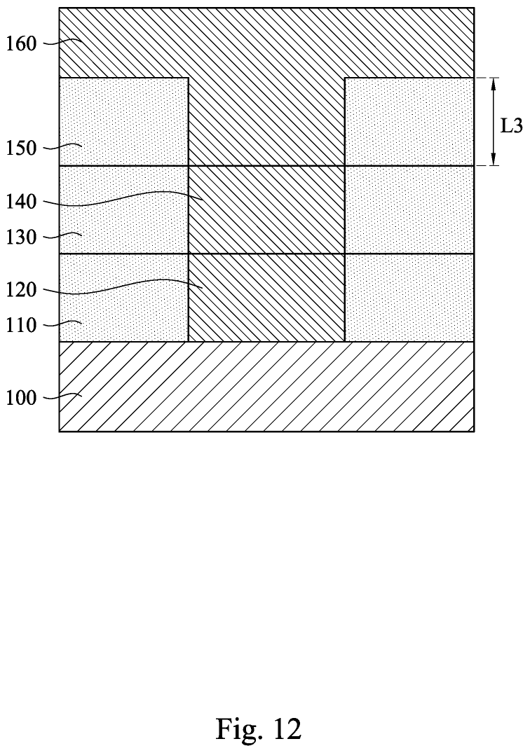

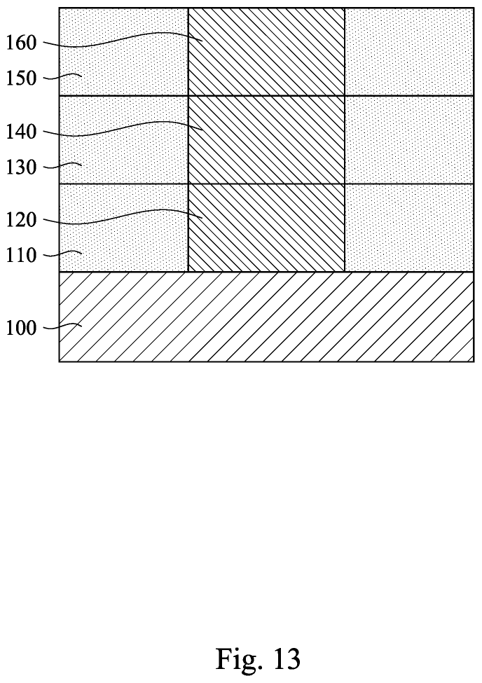

Referring to FIG. 12, a third material 160 is formed overfilling the second trench T3, and then referring to FIG. 13, an excess portion of the third material 160 is removed by performing a planarization process until the top surface of the third photoresist layer 150 is exposed. As a result, the third material 160 is filled in the third trench T3. After filling the third material 160 in the third trench T3, a top surface of the third material 160 is level with a top surface of the third photoresist layer 150, and opposite sidewalls of the third material 160 may be substantially aligned with the opposite sidewalls of the second material 140. In some embodiments, the third material 160 may be the same as the second material 140.

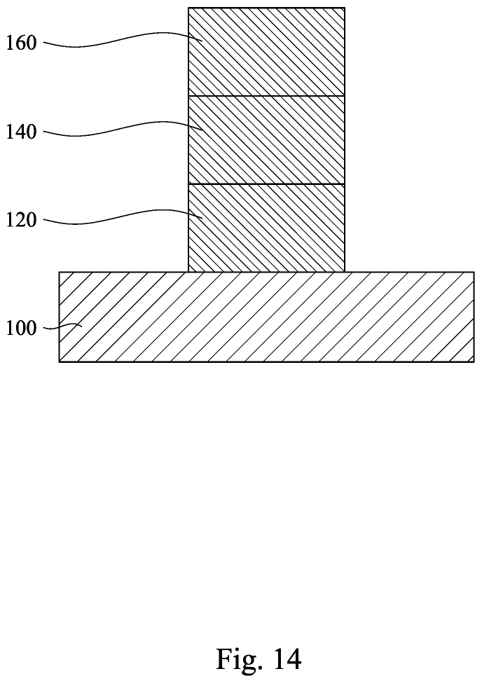

Referring to FIG. 14, after filling the third material 160 in the third trench T3, the first photoresist layer 110, the second photoresist layer 130 and the third photoresist layer 150 are removed. In some embodiments, the first photoresist layer 110, the second photoresist layer 130 and the third photoresist layer 150 are removed by an etching process. In some other embodiments, the first photoresist layer 110, the second photoresist layer 130 and the third photoresist layer 150 are removed using ashing process or stripping. In some embodiments where the first photoresist layer 110, the second photoresist layer 130 and the third photoresist layer 150 are made of the same material, the first photoresist layer 110, the second photoresist layer 130 and the third photoresist layer 150 can be removed together in a single removal process as discussed above. As a result, the first material 120, the second material 140 and the third material 160 remain over the substrate 100 and form a line pattern. Since the first photoresist layer 110, the second photoresist layer 130 and third photoresist layer 150 are thin enough and do not cause severe standing wave effect, the roughness of the first photoresist layer 110, the second photoresist layer 130 and the third photoresist layer 150 is reduced. The line pattern (i.e. the first material 120, the second material 140 and the third material 160) formed in the first photoresist layer 110, the second photoresist layer 130, and the third photoresist layer 150 has less roughness issue. Therefore, in the case that the thickness of the line pattern in the following situation is the same, the line pattern formed in the present disclosure has a better profile compared to the line pattern formed in a single photoresist layer.

It is noted that although the second material 140 and the third material 160 are the same as the first material 120 in this embodiment, the present disclosure is not limited thereto. For example, in some embodiments, the first material 120, the second material 140 and the third material 160 are different from each other. In some other embodiments, the first material 120 is same as the second material 140, and the third material 160 is different from the second material 140. In some other embodiments, the first material 120 is same as the third material 160, and the second material 140 is different from the third material 160. In some other embodiments, the second material 140 is same as the third material 160, and the first material 120 is different from the second material 140.

It is also noted that the number of the photoresist layers for forming the line pattern is not limited to 2 as shown in FIG. 1-10 or 3 as shown in FIGS. 11-14. In some embodiments, the number of the photoresist layers for forming the line pattern may be more than 3. In some embodiments, the number of the photoresist layers for forming the line pattern may be determined by the total thickness of the line pattern. For example, the greater the total thickness of the line pattern is, the more photoresist layers for forming the line pattern are formed. Therefore, even the total thickness of the line pattern is large, such as 1000 nm to 10000 nm, the line pattern is formed with less roughness issue.

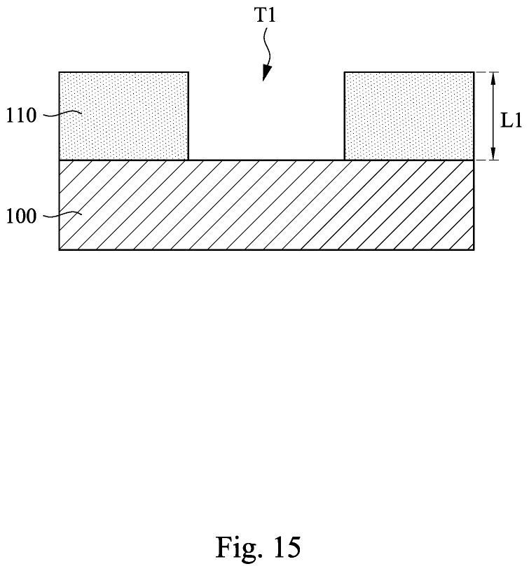

FIGS. 15-19 illustrate cross-section views of forming a line pattern in a semiconductor device in some other embodiments of the present disclosure. Specifically, the line pattern in FIGS. 15-19 may be formed by selective epitaxial growth.

Referring to FIG. 15, a first photoresist layer 110 having a first trench T1 is formed over a substrate 100. The first photoresist layer 110 in FIG. 15 may be similar to the first photoresist layer 110 described in FIG. 1. In FIG. 15, the substrate 100 is a semiconductor layer, such as silicon layer.

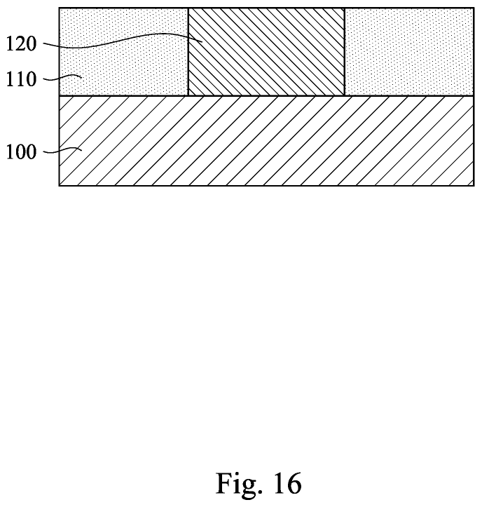

Referring to FIG. 16, a first material 120 is filled in the first trench T1 of the first photoresist layer 110. Specifically, the first material 120 may be filled in the first trench T1 of the first photoresist layer 110 by a selective epitaxial growth process. The first material 120 may be semiconductor material, such as silicon, selectively grown over the substrate 100. During the selective epitaxial growth of the first material 120 over the substrate 100, the silicon of the first material 120 is only grown on the exposed surface of the substrate 100 made of silicon, and is not grown over the first photoresist layer 110. Therefore, the first material 120 is formed in the first trench T1 of the first photoresist layer 110.

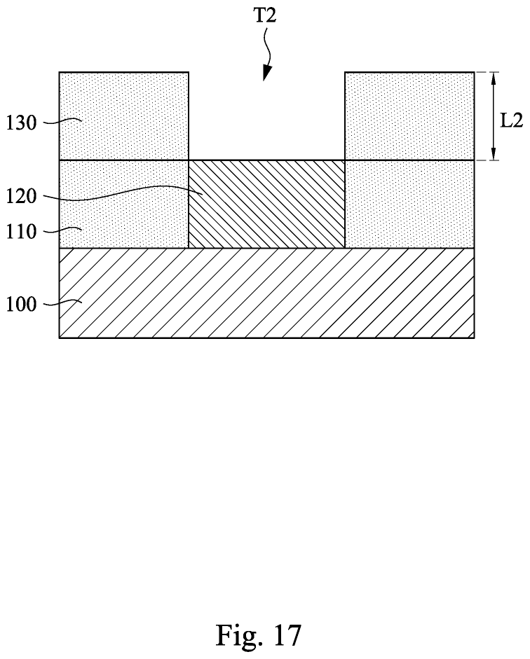

Referring to FIG. 17, a second photoresist layer 130 having a second trench T2 is formed over the first photoresist layer 110. The second photoresist layer 130 in FIG. 17 may be similar to the second photoresist layer 130 described in FIG. 4.

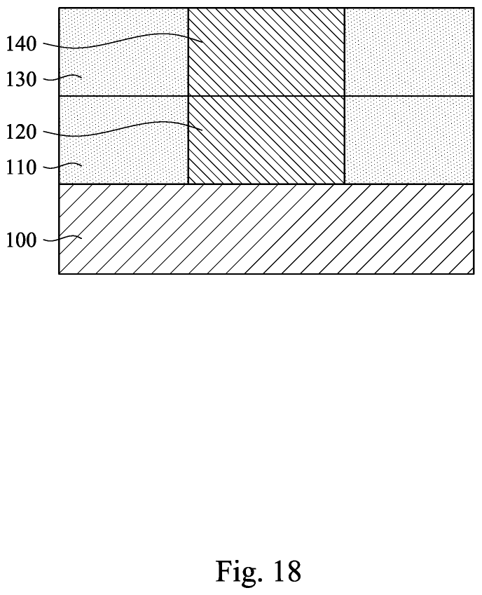

Referring to FIG. 18, a second material 140 is filled in the second trench T2 of the second photoresist layer 130. Specifically, the second material 140 may be filled in the second trench T2 of the second photoresist layer 130 by a selective epitaxial growth process. The second material 140 may be semiconductor material, such as silicon, selectively grown over the first material 120. During the selective epitaxial growth of the second material 140 over the first material 120, the silicon of the second material 140 is only grown on the exposed surface of the first material 120 made of silicon, and is not grown over the second photoresist layer 130. Therefore, the second material 140 is formed in the second trench T2 of the second photoresist layer 130.

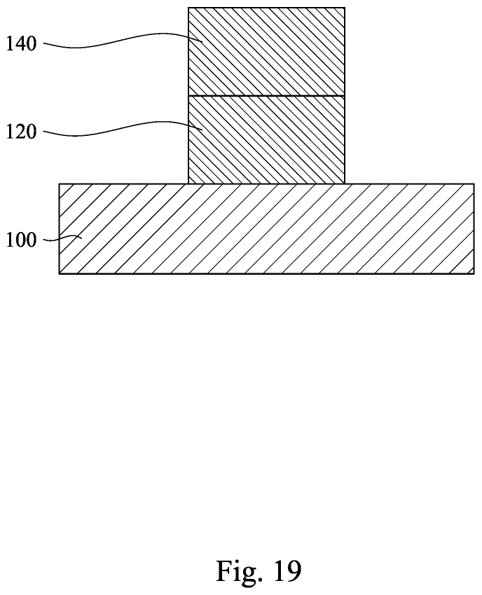

Referring to FIG. 19, the first photoresist layer 110 and the second photoresist layer 130 are removed. The removal process of the first photoresist layer 110 and the second photoresist layer 130 in FIG. 19 is similar to the removal process described in FIG. 7.

As mentioned above, the line pattern is formed by repeating filling the certain material in the trenches in the photoresist layers. The photoresist layers are thin enough, so the photoresist layers are not affected by the standing wave effect much. The number of the photoresist layers for forming the line pattern may be determined by the total thickness of the line pattern, to form the line pattern with great thickness and less roughness at the same time. The materials filled in each photoresist layer may be the same as or different from each other. Therefore, the line pattern may be made of single material or several materials.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a line pattern in a semiconductor device, comprising:
forming a first photoresist layer having a first trench over a substrate;
filling a first material in the first trench;
forming a second photoresist layer having a second trench over the first photoresist layer;
filling a second material in the second trench; and
after filling the second material in the second trench, removing the first photoresist layer and the second photoresist layer.

2. The method of claim 1, wherein the second trench is aligned with the first trench.

3. The method of claim 1, wherein the second material is the same as the first material.

4. The method of claim 1, wherein the second material is different from the first material.

5. The method of claim 1, wherein after filling the first material in the first trench, a top surface of the first material is level with a top surface of the first photoresist layer.

6. The method of claim 5, wherein filling the first material in the first trench comprises:
forming the first material overfilling the first trench; and
removing an excess portion of the first material by performing a planarization process until the top surface of the first photoresist layer is exposed.

7. The method of claim 1, wherein after filling the second material in the second trench, a top surface of the first material is level with a top surface of the second photoresist layer.

8. The method of claim 7, wherein filling the second material in the second trench comprises:
forming the second material overfilling the second trench; and
removing an excess portion of the second material by performing a planarization process until the top surface of the second photoresist layer is exposed.

9. The method of claim 1, wherein the first photoresist layer and the second photoresist layer are removed through a single removal process.

10. The method of claim 1, wherein forming the first photoresist layer having the first trench comprises patterning the first photoresist layer, and forming the second photoresist layer having the second trench comprises patterning the second photoresist layer, and wherein patterning the first photoresist layer and patterning the second photoresist layer are performed using a same mask.

11. A method of forming a line pattern in a semiconductor device, comprising:
forming a first photoresist layer having a first trench over a substrate, wherein the first photoresist layer has a first thickness;
filling a first material in the first trench;
forming a second photoresist layer having a second trench over the first photoresist layer, the second photoresist layer being in contact with the first photoresist layer, wherein the second photoresist layer has a second thickness;
filling a second material in the second trench; and
removing the first photoresist layer and the second photoresist layer.

12. The method of claim 11, wherein opposite sidewalls of the second material is aligned with opposite sidewalls of the first material.

13. The method of claim 11, wherein the first photoresist layer and the second photoresist layer are made of a same material, and the first thickness is substantially the same as the second thickness.

14. The method of claim 11, wherein after filling the first material in the first trench, the first material and the first photoresist layer have substantially a same height.

15. The method of claim 14, wherein filling the first material in the first trench comprises:
forming the first material overfilling the first trench; and
removing an excess portion of the first material by performing a planarization process until a top surface of the first photoresist layer is exposed.

16. The method of claim 11, wherein after filling the second material in the second trench, the second material and the second photoresist layer have substantially a same height.

17. The method of claim 16, wherein filling the second material in the second trench comprises:
forming the second material overfilling the second trench; and
removing an excess portion of the second material by performing a planarization process until a top surface of the second photoresist layer is exposed.

18. The method of claim 11, wherein the first material is filled in the first trench of the first photoresist layer by a first selective epitaxial growth process, and the second material is filled in the second trench of the second photoresist layer by a second selective epitaxial growth process.

19. The method of claim 18, wherein the first material and the second material are made of a semiconductor material.

20. The method of claim 18, wherein the substrate is made of a semiconductor material.
